(19) United States
(12) Patent Application Publication
(10) Pub. No.: US 2015/0017774 A1
(43) Pub. Date: Jan. 15, 2015

(54) METHOD OF FORMING FINS WITH RECESS SHAPES

(71) Applicant: GLOBALFOUNDRIES INC., Grand Cayman (KY)

(72) Inventors: Wei Hua TONG, Mechanicville, NY (US); Hong YU, Rexford, NY (US); Jin Ping LIU, Hopewell Junction, NY (US); Hyucksoo YANG, Watervliet, NY (US); Lun ZHAO, Ballston Lake, NY (US); Chandra REDDY, Lagrangeville, NY (US)

(21) Appl. No.: 13/938,786

(22) Filed: Jul. 10, 2013

(51) Int. Cl. H01L 29/66; H01L 21/02

(52) U.S. Cl. CPC H01L 29/66818; H01L 21/0223; H01L 21/02065
USPC 438/283; 438/778

(57) ABSTRACT

Thermal oxidation treatment methods and processes used during fabrication of semiconductor devices are provided. One method includes, for instance: obtaining a device with at least one cavity etched into the device; performing a thermal oxidation treatment to the at least one cavity; and cleaning the at least one cavity. One process includes, for instance: providing a semiconductor device with a substrate, at least one layer over the substrate and at least one fin; forming at least one gate over the fin; doping at least one region below the fin; applying a spacer layer over the device; etching the spacer layer to expose at least a portion of the gate material; etching a cavity into the at least one fin; etching a shaped opening into the cavity; performing thermal oxidation processing on the at least one cavity; and growing at least one epitaxial layer on an interior surface of the cavity.

### FIELD OF THE INVENTION

The present invention relates to semiconductor devices and methods of fabricating semiconductor devices, and more particularly, thermal oxidation treatments for fabricating shaped semiconductor structures on fins of FinFETs.

### BACKGROUND OF THE INVENTION

Semiconductor devices may include FIN structures which include a 110 recessed plane under the channel. However, the FIN structures may have a very small area with complex oxide and nitride around the FIN structures or native oxide present after etching, which may create several disadvantages, such as a lack of post cavity etch uniformity and undesirable surface morphology. The lack of uniformity of the cavity and surface of the semiconductor devices may lead to more epitaxial defects and problems due to the lack of surface uniformity.

As the cavity is formed for the FIN structures it may be generally rounded and shallow and lack a well defined shape. In addition, the surrounding surface may include surface contamination. The lack of a well defined shape and surface contamination on the FIN structures may result in unconformal Epi growth, Epi growth with stacking faults and a smaller epitaxial volume for the FIN structures, which decreases performance of the semiconductor devices.

Thus, there is a need for an improved method of fabricating semiconductor devices to improve the channel mobility.

### BRIEF SUMMARY

The shortcomings of the prior art are overcome and additional advantages are provided through the provision, in one aspect, of a method which includes, for instance: obtaining a device with at least one cavity etched into the device; performing a thermal oxidation treatment to the at least one cavity; and cleaning the at least one cavity.

In another aspect, a process is presented which includes, for instance: providing an intermediate semiconductor device with a substrate, at least one layer on top of the substrate, and at least one fin; forming at least one gate over the fin; doping at least one region below the fin; applying a spacer layer over the semiconductor device; etching the spacer layer to expose at least a portion of the gate material; etching a cavity into the at least one fin; etching a shaped opening into the cavity; performing thermal oxidation processing on the at least one cavity; and growing at least one epitaxial layer on an interior surface of the cavity.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a structure obtained during a fin formation approach, in accordance with one or more aspects of the present invention;

FIG. 2 depicts a fin of FIG. 1, in accordance with one or more aspects of the present invention;

FIG. 3 depicts the structure of FIG. 1 after application of a gate material over the fins and isolation regions, in accordance with one or more aspects of the present invention;

FIG. 4 depicts the structure of FIG. 2 after the application of a barrier layer and a second dielectric layer, in accordance with one or more aspects of the present invention;

FIG. 5 depicts an alternative view of the structure of FIG. 4, in accordance with one or more aspects of the present invention;

FIG. 6 depicts the structure of FIG. 4 after the gates are etched and a spacer layer is applied over the structure, in accordance with one or more aspects of the present invention;

FIG. 7 depicts a portion of the structure of FIG. 6 after performing a spacer etch, in accordance with one or more aspects of the present invention;

FIG. 8 depicts an alternative view of the portion of the structure in FIG. 7, in accordance with one or more aspects of the present invention;

FIG. 9 depicts another embodiment of the structure of FIG. 7 after recessing at least one fin, in accordance with one or more aspects of the present invention;

FIG. 10 depicts an alternative view of a portion of the structure of FIG. 9, in accordance with one or more aspects of the present invention;

FIG. 11 depicts one embodiment of the structure of FIG. 7 after etching a shaped opening in the at least one fin, in accordance with one or more aspects of the present invention;

FIG. 12 depicts an alternative view of the portion of the structure of FIG. 11, in accordance with one or more aspects of the present invention;

FIG. 13 depicts the structure of FIG. 9 after etching a shaped opening in the at least one fin, cleaning the at least one cavity and opening that form the at least one fin, and growing epitaxy in the at least one opening of the fin, in accordance with one or more aspects of the present invention;

FIG. 14 depicts a perspective view of one embodiment of a structure obtained during a fin formation approach, in accordance with one or more aspects of the present invention;

FIG. 15 depicts a perspective view of a portion of the structure of FIG. 14, in accordance with one or more aspects of the present invention;

FIG. 16 is a scanning electron microscope image of a cross section of a FinFET;

FIG. 17 is a scanning electron microscope image of a cross section of a FinFET after a thermal oxidation treatment, in accordance with one or more aspects of the present invention;

FIG. 18 depicts one embodiment of a portion of a process for forming a fin using thermal oxidation treatment, in accordance with one or more aspects of the present invention; and

FIG. 19 depicts another embodiment of a portion of a semiconductor fabrication process including using a thermal oxidation treatment to form fins, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

The present disclosure addresses and enhances, inter alia, cavity formation during semiconductor fabrication, more specifically, thermal oxidation treatment during cavity formation of the semiconductor fabrication process. Thermal oxidation treatment includes oxidizing the cavity in order to remove surface contamination and to achieve a desired shape of the cavity. Generally the thermal oxidation treatment enables the creation of a specifically shaped cavity.

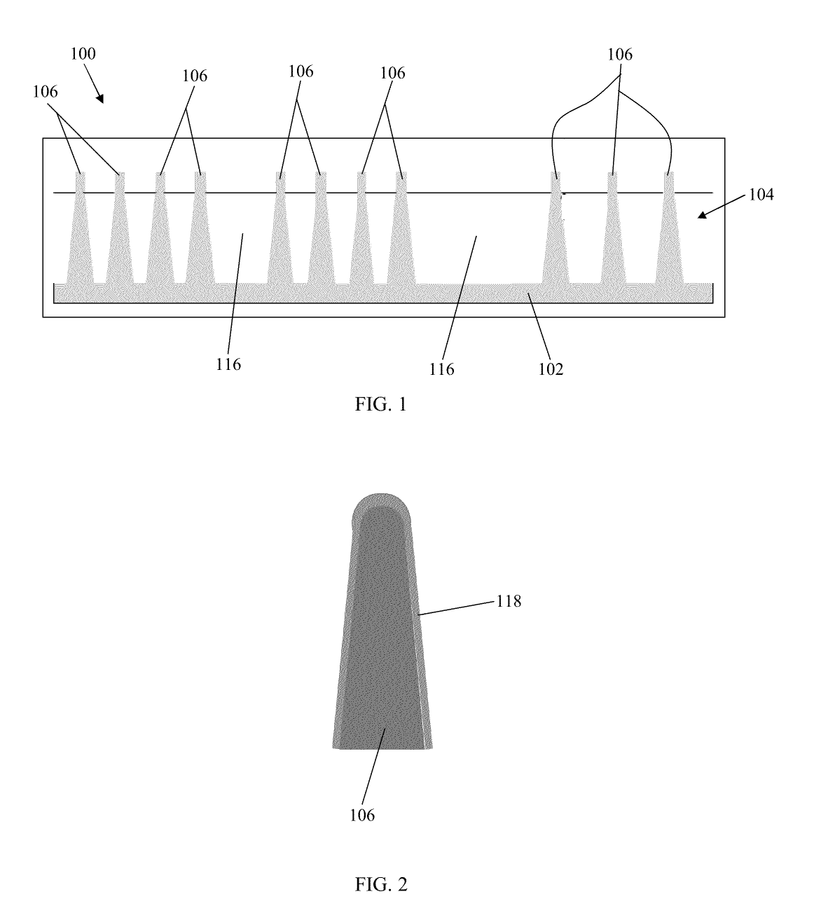

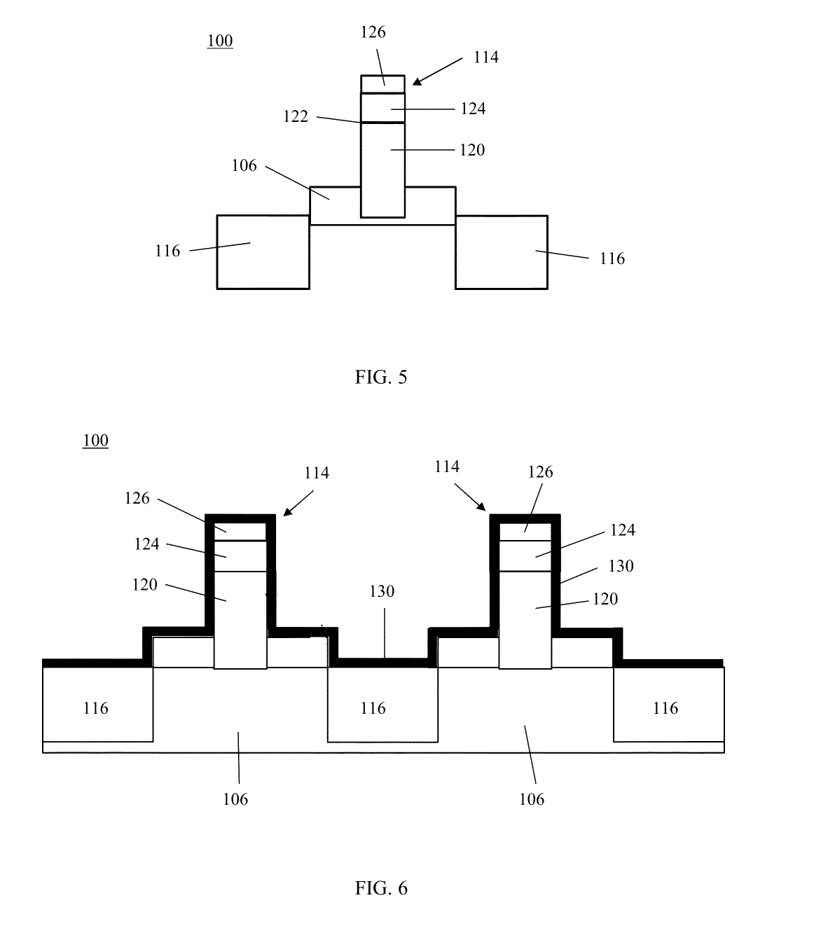

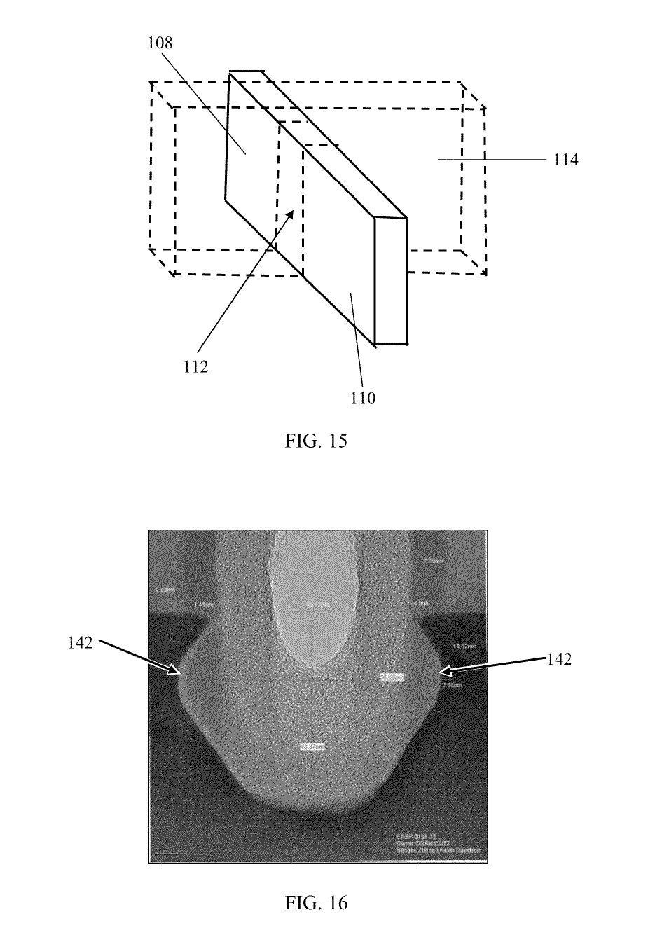

Referring now to the drawings, FIG. 1 shows a cross sectional view of a portion of a FinFET device 100, including a substrate 102 along with a fin structure 104 disposed above the semiconductor substrate, prior to formation of a gate 114 (See FIGS. 5 and 6) during an early stage of fabrication. As understood by one skilled in the art, a FinFET is a field effect transistor with source, drain, and channel regions situated above the substrate in one or more raised structures which may roughly resemble fins in some designs. The fin structure 104 may advantageously assist in controlling current leakage through the transistor in the off stage, and a double gate or tri-gate structure may be employed to control short channel effects. In the present example, the fin structure 104 may include one or more fins, which may be, for example, n-type FinFETs or p-type FinFETs, as described in greater detail below, each FinFET including one or more silicon fins, for example, fin 106. The fins 106 may further be grown with stress-inducing materials, for example, epitaxial silicon materials. Each fin 106 may include areas for a source 108, a drain 110, and a channel 112, as shown in FIGS. 14 and 15. It will be understood that the positioning of the source 108 and drain 110 areas could be switched.

The semiconductor substrate may also include, for example, silicon in a crystalline structure with any suitable crystallographic orientation. Suitable orientations include, for example, (100), (110), and (111) orientations. In the present example, the substrate has a planar (100) crystallographic surface orientation (referred to as (100) surface) and, where the substrate is a wafer, may further include a notch (not shown) at an edge of the wafer, along any suitable direction, for example, <110> (most popular) or <100> direction. It may be noted that the crystal direction is indicated by <100>, and the crystal surface is denoted by (100) as shown. As one skilled in the art will understand, where the substrate is a semiconductor wafer including an orientation notch (in <110> or <100> directions), the fins 106 may be positioned substantially parallel or perpendicular to the direction as defined by the notch (or flat) pointing to <110>or <100> direction. The gate 114 may be positioned substantially perpendicular to the direction of the fins 106 and over a portion of the top and a portion of the side surfaces of the fins 106. Further, the fin 106 may exhibit a generally rounded shape with a top surface having a (100) crystallographic surface orientation and a (110) crystallographic surface for the sidewall surfaces in case the notch is pointing to the <110> direction. Alternatively, the crystallographic orientation of the top surface and the sidewall surfaces of the fins 106 may include a (100) surface orientation, in the case of the substrate including a notch aligned toward <100> direction. The fin structure with the ‘notch’ pointing to, for example, <110>, is discussed in this application.

As shown in FIG. 1, the fins 106 may be laterally separated by corresponding isolation regions 116, for example, shallow isolation trenches (STI). The formation of isolation regions, such as shallow isolation trenches, may typically include forming a recess on the silicon substrate and filling the recess with a dielectric film using a chemical vapor deposition (CVD) process, for example, a low pressure CVD (LPCVD), a high-density CVD (HDCVD), or plasma enhanced CVD (PECVD), then performing a chemical mechanical polish (CMP) to remove any excess dielectric film filling the shallow isolation trenches. The isolation regions 116 may be filled with dielectric materials, for example, silicon oxide, silicon nitride, and the like. The isolation regions 116 may then be annealed. After formation of the isolation regions 116, the fins 106 may be revealed by performing, for example, plasma etching to recess the dielectric materials in the isolation regions 116. The selective etching may, in the present example, result in the top surfaces of the fins 106 maintaining (100) surface orientation, while the slightly sloped sidewalls of the fins 106 are exposed and have nearly a (110) surface orientation.

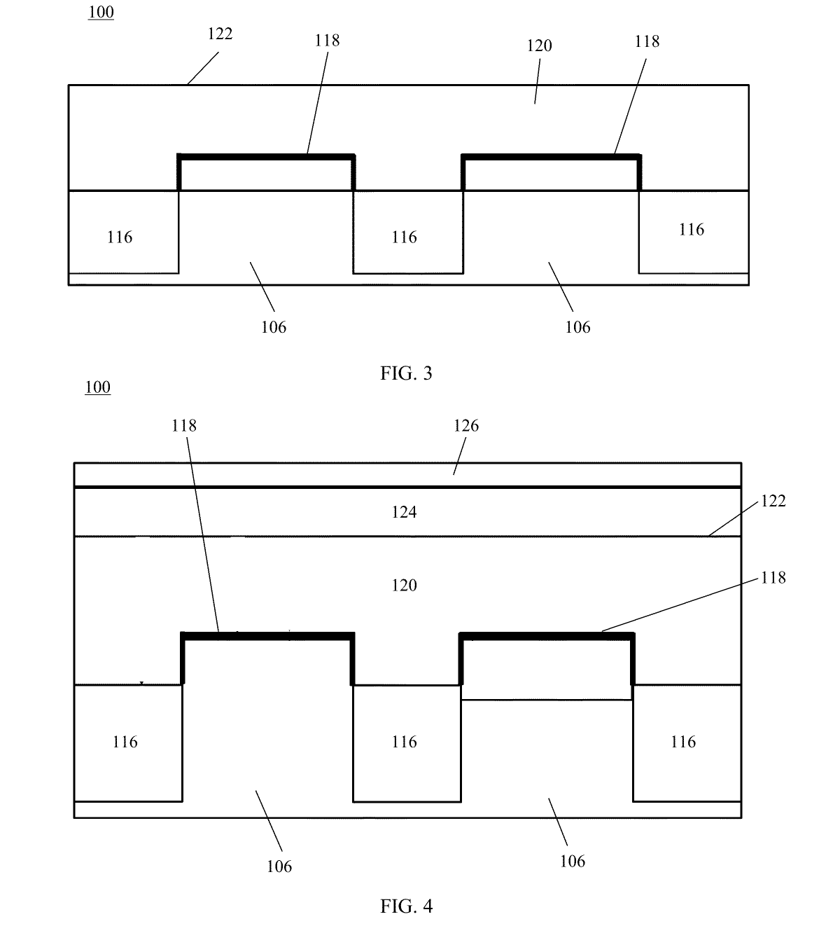

In an example embodiment, a dielectric layer 118, for example, a gate oxide, may be applied over the revealed fins 106, as shown on the fin 106 of FIG. 2. Referring now to FIG. 3, a cross-sectional view of a portion of the device 100 during fabrication. As shown in FIG. 3, the device 100 includes the fins 106 separated by at least one isolation region 116, a dielectric layer 118 is applied over the revealed portion of the fins 106, and a gate material 120 is deposited over the isolation regions 116 and the dielectric layer 118. The gate material 120 may be, for example, amorphous silicon. After the gate material 120 is applied to the device 100, chemical mechanical planarization (CMP) may be performed on the gate material 120. In addition, in one embodiment, a chemox layer 122 may be formed on the gate material 120. The chemox layer 122 may be formed using a known growing technique, including, for example, oxidation or oxynitridation, and using a wet chemical oxidation process.

As shown in FIGS. 4 and 5, a barrier layer 124 may be applied over the gate material 120 or chemox layer 122. The barrier layer 124 may be, for example, silicon mononitride (SiN) or other materials known by those skilled in the art. A second dielectric layer 126 may be applied over the barrier layer 124. The second dielectric layer 126 may be, for example, silicon oxide. After the barrier layer 124 and the second dielectric layer 126 are applied over the gate material 120, a hard mask layer (not shown) may be applied over the second dielectric layer 126 and the device 100 may be etched to form at least one gate 114. The at least one gate 114 may include the gate material 120, barrier layer 124 and the second dielectric layer 126. The at least one gate 114 may include additional layers depending on the design of the semiconductor being fabricated.

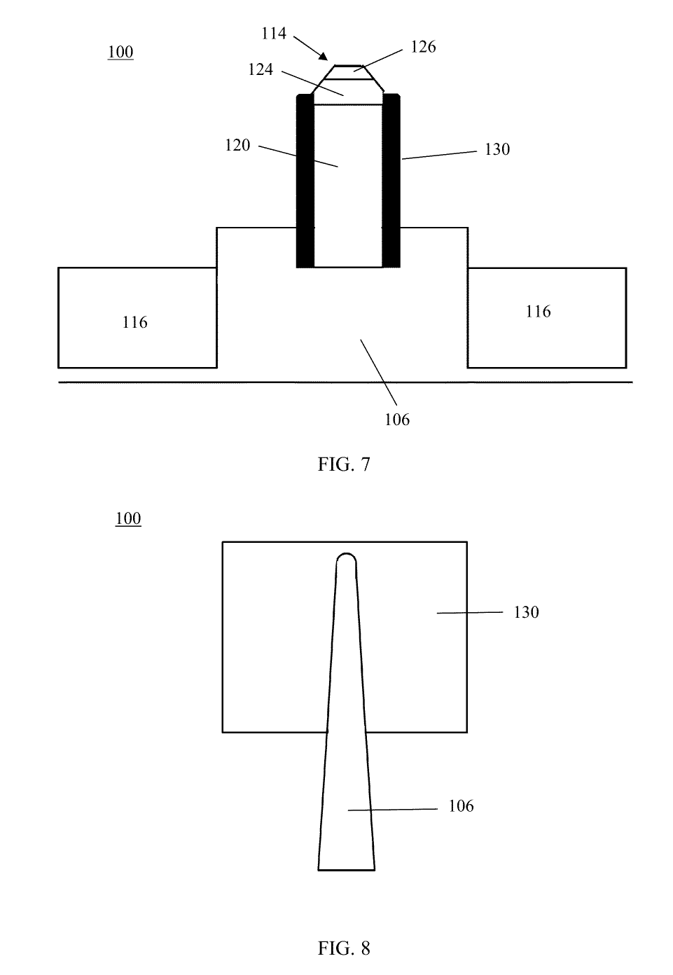

After the at least one gate 114 is etched, halo regions (not shown) may be created by doping the regions below the fins 106, specifically the areas below the source and drain regions 108, 110 of the device 100. As shown in FIG. 6, a spacer layer 130 may be applied over the fins 106, the at least one gate 114, and the isolation regions 116. The spacer layer 130 may then be etched to remove the spacer layer 130 from over the fins 106, isolation regions 116, and a portion of the gate 114. The at least one gate 114 may be shaped, for example, angled as shown in FIGS. 7 and 10, as desired for the semiconductor design. As shown in FIG. 8, the spacer layer 130 creates a side wall around the at least one gate 114 and over the top of a portion of the fin 106.

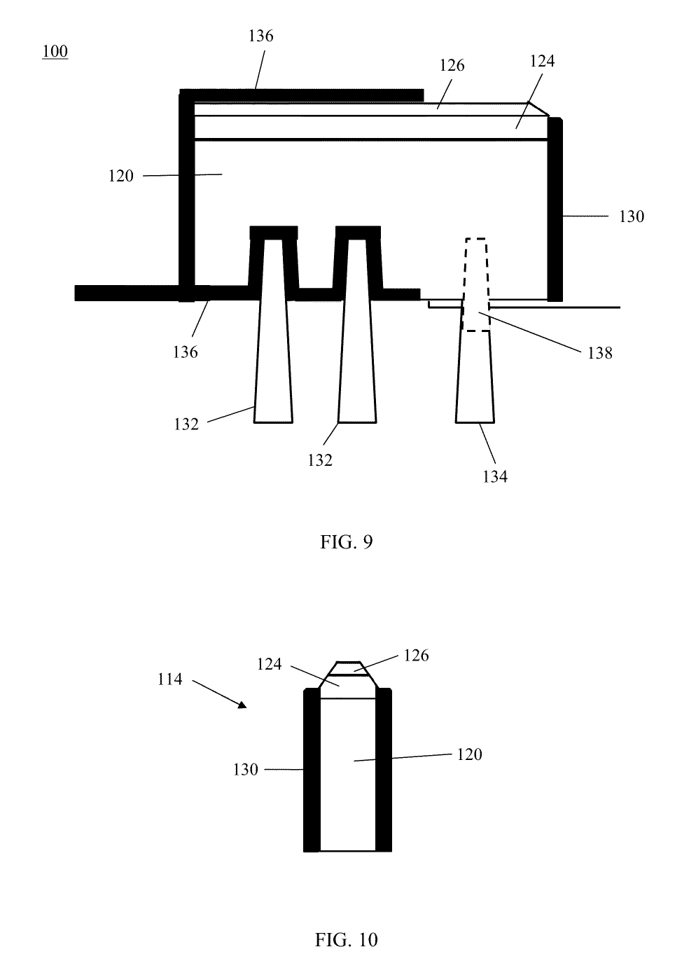

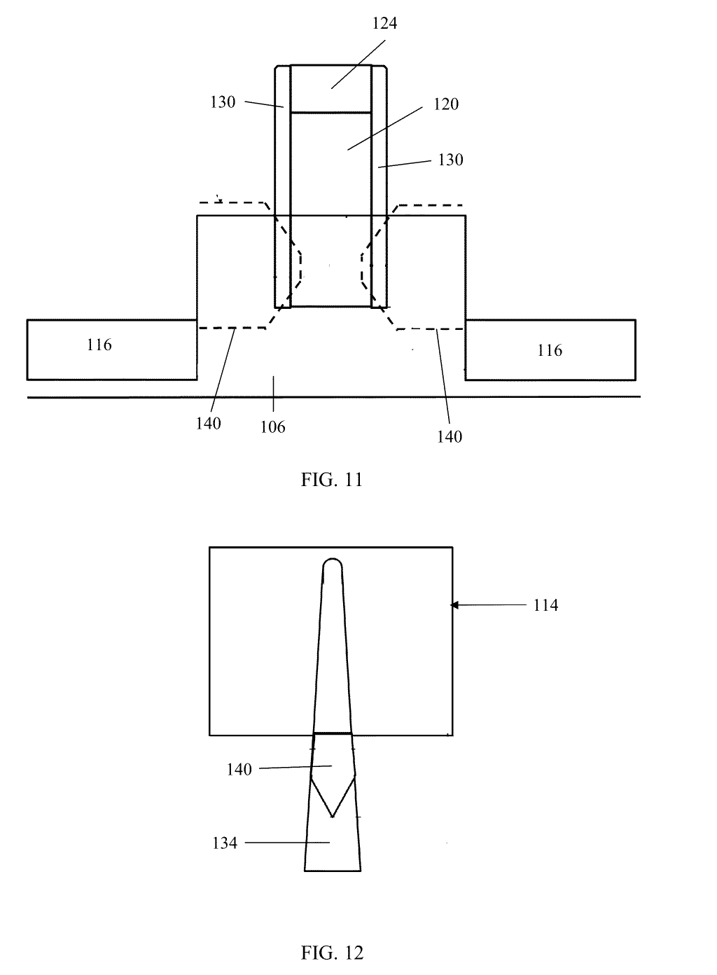

As shown in FIG. 9, the device 100 may include n-type FinFETs 132 and p-type FinFETs 134. In one embodiment, as shown, a mask 136 may be applied over the device 100 aligning the openings in the mask 136 over at least one of the p-type FinFETs 134. An etch process may then be performed over the mask 136 to remove a portion of the p-type FinFETs 134 to create a recess or cavity 138 in the p-type FinFETs 134. The etching of the recess or cavity 138 may be, for example, a p-type metal-oxide semiconductor cavity etch. Next, as shown in FIGS. 11 and 12, the cavity 138 may be etched a second time to shape the cavity 138, for example, by forming a shaped opening 140, for example, a sigma shaped opening, in the cavity 138. The etching processes used to form the cavity 138 may be, for example, wet or dry etching.

Once the etching processes are complete forming the cavity 138 with a shaped opening 140, the cavity may be treated with a thermal oxidation process or treatment. The thermal oxidation process may be performed in order to create a silicon oxide film on the interior surface of the cavity 138 and opening 140. The thermal oxidation process may be performed at a high temperature and in a specific gas environment. In one embodiment, for example, the thermal oxidation treatment may be performed at a temperature between approximately 600° C. and 900° C., and more preferably between about 700° C. and 800° C. In addition, the thermal oxidation treatment may be performed in a gas environment containing, for example, O₂, H₂, N₂, or the like. The thermal oxidation treatment may be performed at, for example, atmospheric pressure or with reduced pressure. By way of example only, one detailed embodiment of the thermal oxidation treatment includes treating the device 100 including at least one cavity 138 with an opening 140 at 700° C. for about 20 seconds in a gas environment containing at least one of O₂, H₂, N₂O, or NO with atmospheric pressure.

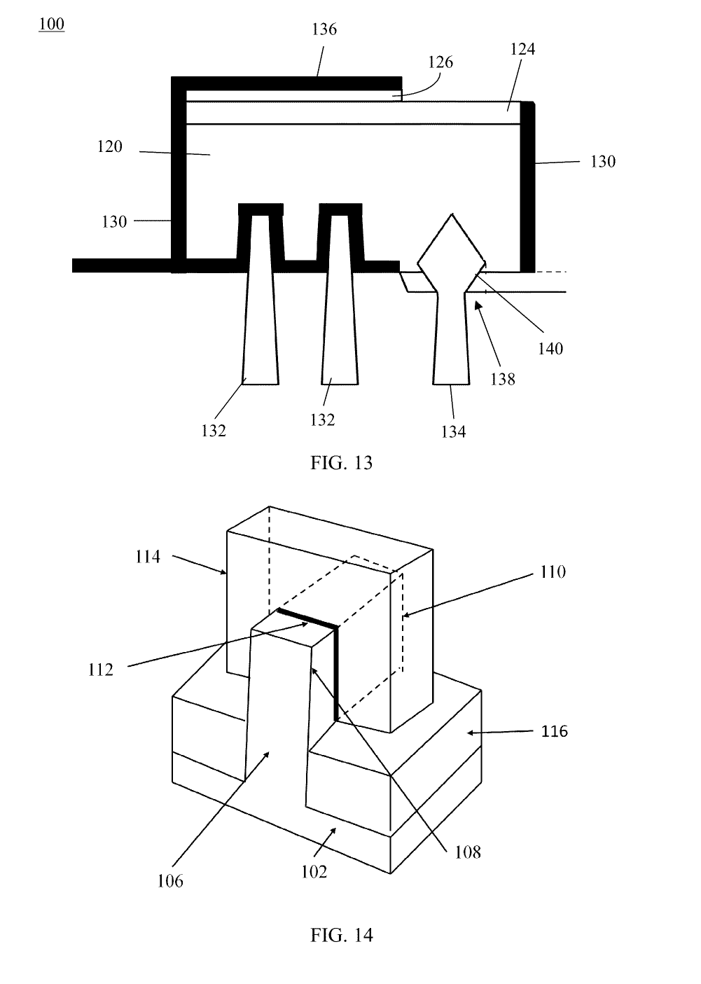

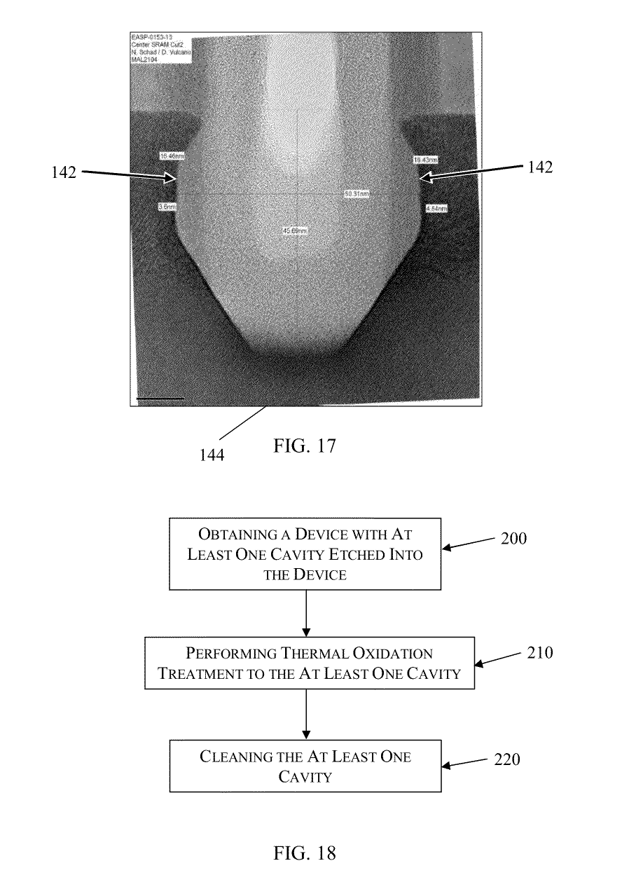

As shown in FIGS. 16 and 17, the thermal oxidation process may create a cavity 138 that is deeper and provides more defined <110> cavity planes 142 and <111> cavity planes 144. The more defined <110> and <111> planes 142, 144 allow for more epitaxial growth volume to be applied to the cavity 138. In addition, the thermal oxidation process may reduce the surface contamination on the surfaces of the <110> and <111> planes 142, 144. The thermal oxidation treatment may also assist in improving the performance of device 100 by modulating the recess shape by, for example, modifying the Si atomic plane. In addition, the performance of the device 100 may be improved by moving the <110> plane 142 closer to the channel 112. In one embodiment, shown in FIG. 13, the <110> plane 142 being closer to the channel 112 (not shown in FIG. 13) improves performance of the p-type FinFET 134.

As shown in FIG. 13, after the cavity 138 with the sigma shaped opening 140 is etched and the thermal oxidation treatment is performed on the cavity 138, a wet or dry clean may be performed to remove any remaining contamination, for example, the thin SiO₂ layer from the surface of the cavity 138 and surface of the device 100. The wet or dry clean may be, for example, a SiCoNi or DHF clean or the like as known to one of ordinary skill in the art. Once the device 100 including the cavity 138 is cleaned epitaxial growth may be grown into the cavity 138 including the opening 140, and optionally into the rest of the fin 106. The epitaxial growth may be, for example, in one embodiment silicon-germanium (SiGe). The fins 106 may also have, for example, one or more compressive stress inducing materials or one or more tensile stress inducing materials epitaxially grown thereon. In another embodiment, the tensile stress inducing material may be, for example, silicon doped with carbon (Si:C), which may be epitaxially grown on top of the silicon (Si) fins for p-FinFET5 134.

In one aspect, in one embodiment, as shown in FIG. 18, a portion of the semiconductor device fabrication method or process in accordance with one or more aspects of the present invention may include, obtaining a device with at least one cavity etched into the device 200, performing a thermal oxidation process to the at least one cavity 210, and cleaning the at least one cavity 220.

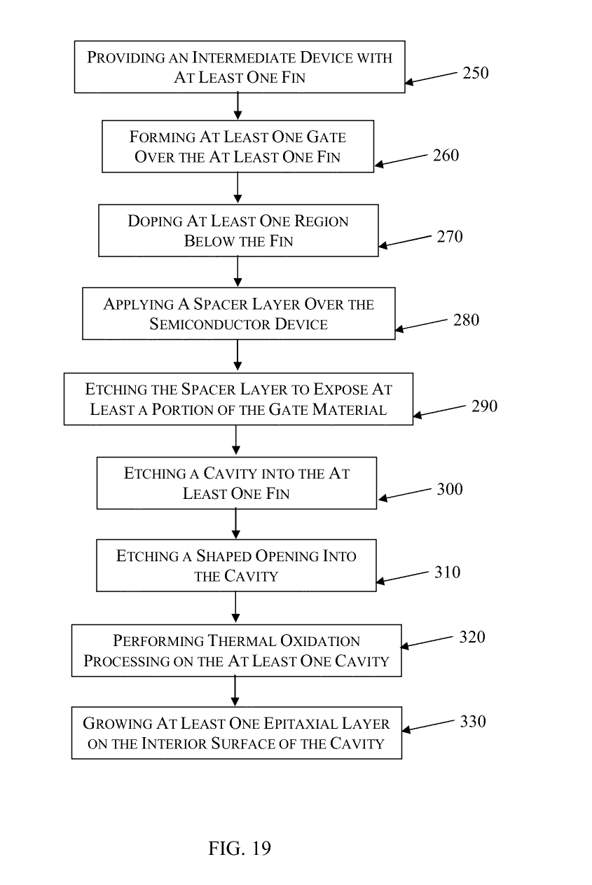

As shown in FIG. 19, in another aspect, a portion of the semiconductor device fabrication process in accordance with one or more aspects of the present invention may include, providing an intermediate semiconductor device 250, including a substrate, at least one layer on top of the substrate and at least one fin, forming at least one gate over the fin 260, doping at least one region below the fin 270, applying a spacer layer over the semiconductor device 280, etching the spacer layer to expose at least a portion of the gate material 290, etching a cavity into the at least one fin 300, etching a shaped opening into the cavity 310, performing thermal oxidation processing on the at least one cavity 320, and growing at least one epitaxial layer on an interior surface of the cavity 330.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method, comprising:
obtaining a device with at least one cavity etched into the device;
performing a thermal oxidation treatment to the at least one cavity; and
cleaning the at least one cavity.

2. The method of claim 1, wherein performing the thermal oxidation treatment comprises:
oxidizing surface contamination from the at least one cavity.

3. The method of claim 1, wherein the thermal oxidation treatment is performed at a temperature ranging from about 600° C. to about 900° C.

4. The method of claim 1, wherein the thermal oxidation treatment is performed at a temperature ranging from about 700° C. to about 800° C.

5. The method of claim 1, wherein the thermal oxidation treatment is performed in an environment containing at least one gas.

6. The method of claim 5, wherein the at least one gas is selected from the group consisting of O₂, H₂, N₂O, and NO.

7. The method of claim 3, wherein the thermal oxidation treatment is performed with at least one gas selected from the group consisting of O₂, H₂, N₂O, and NO.

8. The method of claim 4, wherein the thermal oxidation treatment is performed in an environment with at least one gas selected from the group consisting of O₂, H₂, N₂O, and NO.

9. The method of claim 1, wherein the thermal oxidation treatment is performed at a reduced pressure.

10. The method of claim 1, wherein the thermal oxidation treatment is performed at atmospheric pressure.

11. The method of claim 1, wherein the at least one etched cavity includes a shaped opening.

12. The method of claim 11, wherein the shaped opening has a sigma shape.

13. A process, comprising:
providing an intermediate semiconductor device, comprising:
a substrate;
at least one layer on top of the substrate; and
at least one fin;
forming at least one gate over the fin;
doping at least one region below the fin;
applying a spacer layer over the semiconductor device;
etching the spacer layer to expose at least a portion of the gate material;
etching a cavity into the at least one fin;
etching a shaped opening into the cavity;
performing thermal oxidation processing on the at least one cavity; and
growing at least one epitaxial layer on an interior surface of the cavity.

14. The process of claim 13, wherein the thermal oxidation processing on the at least one cavity comprises:
oxidizing surface contamination from the at least one cavity.

15. The process of claim 13, wherein the thermal oxidation processing is performed at a temperature ranging from about 600° C. to about 900° C.

16. The process of claim 13, wherein the thermal oxidation processing is performed at a temperature ranging from about 700° C. to about 800° C.

17. The process of claim 13, wherein the thermal oxidation processing is performed in an environment containing at least one gas.

18. The method of claim 17, wherein the gas is selected from the group consisting of O₂, H₂, N₂O, and NO.

19. The process of claim 13, further comprising:
cleaning the at least one cavity prior to growing the at least one epitaxial layer.

20. The process of claim 19, wherein the cleaning of the at least one cavity comprises:
performing a clean selected from the group consisting of SiCoNi clean and a DHF clean.
